(19) United States
(12) Patent Application Publication
(10) Pub. No.: US 2026/0305091 A1
(43) Pub. Date: Oct. 1, 2026

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Chao ZHANG, Beijing (CN); Yongliang ZHAO, Beijing (CN)

(21) Appl. No.: 19/479,336

(22) PCT Filed: Jan. 10, 2025
(86) PCT No.: PCT/CN2025/071768

§ 371 Date: Oct. 27, 2025

(30) Foreign Application Priority Data
Jan. 23, 2024 (CN) 202410096342.1

(51) Int. Cl. H10K 59/131; H10K 59/121

(52) U.S. Cl. CPC H10K 59/131; H10K 59/1213; H10K 59/1216

(57) ABSTRACT

A display substrate and a display apparatus. The display substrate comprises a base and at least one pixel driving circuit located on one side of the base, wherein the at least one pixel driving circuit comprises at least one transistor, the at least one transistor comprises an active layer, and the active layer comprises a channel region, and a first region and a second region which are located on two opposite sides of the channel region; the first region has a first end and a second end which are arranged opposite each other, the first end of the first region is connected to the channel region, and the second end extends in a second direction; and the channel region has a first width in a first direction, and the first region has a second width in the first direction, the first width being greater than the second width.

### CROSS-REFERENCE TO RELATED APPLICATIONS

The present application is a U.S. National Phase Entry of International Application No. PCT/CN2025/071768 having an international filing date of Jan. 10, 2025, which claims priority to Chinese patent application No. 202410096342.1, filed to CNIPA on Jan. 23, 2024 and entitled “Display Substrate and Display Apparatus”. Contents of the above-identified applications are incorporated into the present application by reference.

### TECHNICAL FIELD

The present disclosure relates to, but is not limited to, the field of display technologies, and particularly relates to a display substrate and a display apparatus.

### BACKGROUND

An organic light emitting diode (OLED) and a quantum dot light emitting diode (QLED) are active light emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display apparatus (Flexible Display) in which an OLED or a QLED is used as a light emitting device and signal control is performed through a thin film transistor (TFT) has become a mainstream product in the field of display at present.

### SUMMARY

The following is a summary of subject matters described herein in detail. This summary is not intended to limit the protection scope of claims.

Embodiments of the present disclosure provide a display substrate and a display apparatus.

In one aspect, an embodiment of the present disclosure provides a display substrate including a base substrate and at least one pixel driving circuit located on a side of the base substrate. The at least one pixel driving circuit includes at least one transistor, the at least one transistor includes an active layer, and the active layer includes a channel region and a first region and a second region located on opposite sides of the channel region. The first region has a first end and a second end oppositely disposed, the first end of the first region is connected to the channel region, and the second end extends along a second direction.

The channel region has a first width along a first direction, the first region has a second width along the first direction, and the first width is greater than the second width. The display substrate further includes a compensation line, a first end of the compensation line is connected to the channel region, and a second end of the compensation line is connected to the second end of the first region. The first direction intersects with the second direction.

In some exemplary embodiments, an absolute value of a difference between the first width and the second width is greater than 10% of the first width.

In some exemplary embodiments, the display substrate further includes at least one capacitor, and the at least one capacitor is closer to the base substrate than the compensation line, and the at least one capacitor is located on a side of an extension direction of the compensation line. A capacitor of the at least one capacitor includes two plates disposed oppositely, and an orthographic projection of the compensation line on the base substrate does not overlap with either of orthographic projections of the two plates on the base substrate.

In some exemplary embodiments, the compensation line and the active layer are disposed in a same layer.

In some exemplary embodiments, the display substrate further includes a first connection bridge, and the first connection bridge has a first end and a second end disposed oppositely along the first direction. The first end of the first connection bridge is connected to the second end of the compensation line, and the second end of the first connection bridge is connected to the second end of the first region of the active layer.

In some exemplary embodiments, the display substrate further includes at least one second connection bridge. The at least one second connection bridge is located between the first connection bridge and the channel region, and located between the first region and the compensation line. A second connection bridge of the at least one second connection bridge extends along the first direction and includes a first end and a second end disposed oppositely. The first end of the second connection bridge is connected to the compensation line, and the second end of the second connection bridge is connected to the first region.

In some exemplary embodiments, the first connection bridge, the at least one second connection bridge, and the compensation line are connected to each other to form an integral structure.

In some exemplary embodiments, the compensation line is located on a side of the active layer away from the base substrate.

In some exemplary embodiments, in a plane perpendicular to the display substrate, the display substrate further includes a semiconductor layer, a first source-drain metal layer, and a second source-drain metal layer located sequentially on a side of the base substrate. The active layer is located in the semiconductor layer, and the compensation line is located in the first source-drain metal layer or the second source-drain metal layer.

In some exemplary embodiments, the display substrate further includes a first bridge electrode and a second bridge electrode. An orthographic projection of the first bridge electrode on the base substrate at least partially overlaps with an orthographic projection of the first end of the first region on the base substrate, and an orthographic projection of the second bridge electrode on the base substrate at least partially overlaps with an orthographic projection of the second end of the first region on the base substrate. An orthographic projection of the compensation line on the base substrate partially overlaps with both the orthographic projection of the first bridge electrode on the base substrate and the orthographic projection of the second bridge electrode on the base substrate.

The compensation line is connected to the first end of the first region through the first bridge electrode, and the compensation line is connected to the second end of the first region through the second bridge electrode.

In some exemplary embodiments, the first bridge electrode and the second bridge electrode are both located in the first source-drain metal layer, and the compensation line is located in the second source-drain metal layer.

In some exemplary embodiments, the orthographic projection of the compensation line on the base substrate at least partially overlaps with an orthographic projection of the first region on the base substrate.

In some exemplary embodiments, the orthographic projection of the compensation line on the base substrate is within an orthographic projection of the first region on the base substrate.

In some exemplary embodiments, the at least one transistor is a drive transistor; the at least one pixel driving circuit further includes a light emitting control transistor connected to the second end of the first region.

In another aspect, an embodiment of the present disclosure provides a display apparatus including the display substrate described in any one of the embodiments.

Other aspects of the present disclosure may be comprehended after the drawings and the detailed descriptions are read and understood.

### BRIEF DESCRIPTION OF DRAWINGS

Accompanying drawings are used to provide an understanding of technical solutions of the present disclosure, and form a part of the specification. The accompanying drawings and embodiments of the present disclosure are adopted to explain the technical solutions of the present disclosure, and do not form limitations on the technical solutions of the present disclosure. Shapes and sizes of one or more components in the drawings do not reflect actual scales, but are only intended to schematically describe contents of the present disclosure.

FIG. 1 is a schematic diagram of a structure of a display apparatus;

FIG. 2 is a schematic diagram of a planar structure of a display substrate;

FIG. 3 is a schematic diagram of a cross-sectional structure of a display substrate;

FIG. 4 is an equivalent circuit diagram of a pixel driving circuit of a display substrate according to an embodiment of the present disclosure;

FIG. 4A is an equivalent circuit diagram of a pixel driving circuit of a display substrate according to another embodiment of the present disclosure;

FIG. 4B is an equivalent circuit diagram of a pixel driving circuit of a display substrate according to yet another embodiment of the present disclosure;

FIG. 5 is a schematic diagram of a local planar structure of a display substrate according to an embodiment of the present disclosure;

FIG. 6 is a schematic diagram of a display substrate after a pattern of a first conductive layer is formed according to an embodiment of the present disclosure;

FIG. 7A and FIG. 7B are schematic diagrams of a display substrate after a pattern of a second conductive layer is formed according to an embodiment of the present disclosure;

FIG. 8A and FIG. 8B are schematic diagrams of a display substrate after a pattern of a semiconductor layer is formed according to an embodiment of the present disclosure;

FIG. 9A and FIG. 9B are schematic diagrams of a display substrate after a pattern of a third conductive layer is formed according to an embodiment of the present disclosure;

FIG. 10 is a schematic diagram of a display substrate after a pattern of a fourth insulating layer is formed according to an embodiment of the present disclosure;

FIG. 11A and FIG. 11B are schematic diagrams of a display substrate after a pattern of a fourth conductive layer is formed according to an embodiment of the present disclosure;

FIG. 12 is a schematic diagram of a local planar structure of a display substrate according to another embodiment of the present disclosure;

FIG. 13A and FIG. 13B are schematic diagrams of a display substrate after a pattern of a semiconductor layer is formed according to another embodiment of the present disclosure;

FIG. 14 is a schematic diagram of a display substrate after a pattern of a fourth insulating layer is formed according to another embodiment of the present disclosure;

FIG. 15A and FIG. 15B are schematic diagrams of a display substrate after a pattern of a fourth conductive layer is formed according to another embodiment of the present disclosure;

FIG. 16 is a schematic diagram of a display substrate after a pattern of a fifth insulating layer is formed according to another embodiment of the present disclosure; and

FIG. 17A and FIG. 17B are schematic diagrams of a display substrate after a pattern of a fifth conductive layer is formed according to another embodiment of the present disclosure.

### DETAILED DESCRIPTION

The embodiments of the present disclosure will be described below with reference to the drawings in detail. Implementations may be implemented in multiple different forms. Those of ordinary skills in the art can easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. In the present disclosure, “a plurality of/multiple” means two or more than two.

In the present disclosure, for convenience, expressions indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the drawings, they are employed for ease of description of the specification and simplification of the description only, but do not indicate or imply that the referred device or element must have a particular orientation, or is constructed and operated in a particular orientation, and therefore cannot be construed as limitations on the present disclosure. The positional relationships between the constituent elements are changed as appropriate based on directions according to which the constituent elements are described. Therefore, appropriate replacements based on situations are allowed, which is not limited to the expressions in the specification.

In the present disclosure, the terms “mounting”, “coupling” and “connection” are to be understood broadly, unless otherwise expressly specified and defined. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand meanings of the aforementioned terms in the present disclosure according to situations.

In the present disclosure, “electric connection” includes a case where constituent elements are connected through an element with a certain electrical effect. The “element with a certain electrical effect” is not particularly limited as long as electrical signals between the connected constituent elements can be transmitted. Examples of the “element with a certain electrical effect” not only include electrodes and wirings, but also include switching elements such as transistors, resistors, inductors, capacitors, other elements with one or more functions, and the like.

In the present disclosure, a transistor refers to an element including at least three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. In the present disclosure, the channel region refers to a region through which a current mainly flows.

In the present disclosure, a first electrode may be a drain electrode and a second electrode may be a source electrode, or a first electrode may be a source electrode and a second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the present disclosure, “film” and “layer” are interchangeable. For example, a “conductive layer” may be replaced with a “conductive film” sometimes. Similarly, an “insulation film” may be replaced with an “insulating layer” sometimes.

In the present disclosure, “about” or “approximately” means that a boundary is defined not so strictly and numerical values within process and measurement error ranges are allowed.

Triangle, rectangle, trapezoid, pentagon, hexagon or the like in the present disclosure are not strictly defined, and they may be approximate triangle, rectangle, trapezoid, pentagon, hexagon, and the like. There may be some small deformations caused by tolerance, and there may be chamfer, arc edge, deformation, or the like.

An embodiment of the present disclosure provides a display substrate including a base substrate and at least one pixel driving circuit located on a side of the base substrate. The at least one pixel driving circuit includes at least one transistor, the at least one transistor includes an active layer, and the active layer includes a channel region, and a first region and a second region located on opposite sides of the channel region. The first region has a first end and a second end oppositely disposed, the first end of the first region is connected to the channel region, and the second end extends along a second direction.

The channel region has a first width along a first direction, the first region has a second width along the first direction, and the first width is greater than the second width. The display substrate further includes a compensation line, a first end of the compensation line is connected to the channel region, and a second end of the compensation line is connected to the second end of the first region. The first direction intersects with the second direction.

In the display substrate according to the embodiment of the present disclosure, by defining the relationship between the first width and the second width, and by providing the compensation line, the problem of threshold voltage divergence of the transistor can be avoided, and the operational performance of the transistor can be improved.

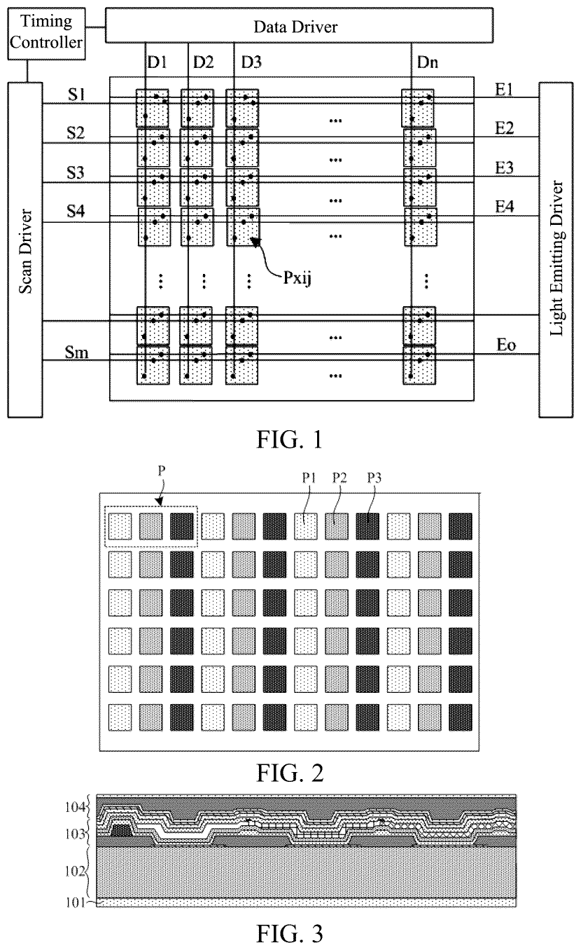

FIG. 1 is a schematic diagram of a structure of a display apparatus. As shown in FIG. 1, the display apparatus may include a timing controller, a data driver, a scan driver, a light emitting driver, and a pixel array. The timing controller is connected to the data driver, the scan driver, and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, and the circuit unit may at least include a pixel driving circuit connected to a scan signal line, a light emitting signal line and a data signal line, respectively. The light emitting unit may include a light emitting device connected to the pixel driving circuit of the circuit unit. In an exemplary embodiment, the timing controller may provide the data driver with a grayscale value and a control signal which are suitable for a specification of the data driver, provide the scan driver with a clock signal and a scan start signal and the like which are suitable for a specification of the scan driver, and provide the light emitting driver with a clock signal and an emission stop signal and the like which are suitable for a specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may generate an emission signal to be provided to the light emitting signal lines E1, E2, E3, . . . , and Eo by receiving a clock signal, an emission stop signal and the like from the timing controller. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be arranged on a display substrate.

FIG. 2 is a schematic diagram of a planar structure of a display substrate. In an exemplary implementation, the display substrate may include a display area and a bezel area located on a periphery of the display area. As shown in FIG. 2, the display area of the display substrate may include a plurality of pixel units P arranged in a matrix. At least one of the pixel units P may include a first sub-pixel P1 emitting light in a first color, a second sub-pixel P2 emitting light in a second color, and a third sub-pixel P3 emitting light in a third color. Each sub-pixel may include a circuit unit and a light emitting unit. The circuit unit may at least include a pixel driving circuit, and the pixel driving circuit is connected to a scan signal line, a data signal line, and a light emitting signal line respectively, and is configured to receive a data voltage transmitted by the data signal line and output a corresponding current to the light emitting device under control of the scan signal line and the light emitting signal line. The light emitting unit may at least include a light emitting device. The light emitting device is connected to a pixel driving circuit of a sub-pixel where the light emitting device is located. The light emitting device is configured to emit light with a corresponding brightness in response to a current output by the pixel driving circuit of the sub-pixel where the light emitting device is located.

In some exemplary embodiments, the first sub-pixel P1 may be a red sub-pixel (R) emitting red light, the second sub-pixel P2 may be a blue sub-pixel (B) emitting blue light, and the third sub-pixel P3 may be a green sub-pixel (G) emitting green light. In an example, a shape of a sub-pixel may be a rectangle, a rhombus, a pentagon, or a hexagon. Three sub-pixels may be arranged side by side horizontally, side by side vertically, or in a manner of a Chinese character “HH” and the like, which is not limited here in the present disclosure.

In some exemplary embodiments, a pixel unit may include four sub-pixels, and the four sub-pixels may be arranged side by side horizontally, side by side vertically, or in a manner of forming a square and the like, which is not limited here in the present disclosure.

FIG. 3 is a schematic diagram of a cross-sectional structure of a display substrate, which illustrates a structure of three sub-pixels of the display substrate. As shown in FIG. 3, in a plane perpendicular to the display substrate, a display area of the display substrate may include a drive circuit layer 102 arranged on a base substrate 101, a light emitting structure layer 103 arranged on a side of the drive circuit layer 102 away from the base substrate 101, and an encapsulation structure layer 104 arranged on a side of the light emitting structure layer 103 away from the base substrate 101. In some possible implementations, the display substrate may further include other film layers, such as a touch structure layer, which is not limited here in the present disclosure.

In some exemplary embodiments, the base substrate 101 may be a flexible base substrate, or may be a rigid base substrate. The rigid base substrate may be, but is not limited to, one or more of glass and quartz. The flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In some exemplary embodiments, the base substrate 101 may be a flexible base substrate, or may be a rigid base substrate. The flexible base substrate may include a first flexible material layer, a first inorganic material layer, a semiconductor layer, a second flexible material layer and a second inorganic material layer which are stacked. Materials of the first flexible material layer and the second flexible material layer may be polyimide (PI), polyethylene terephthalate (PET) or a polymer soft film with surface treatment. Materials of the first inorganic material layer and the second inorganic material layer may be silicon nitride (SiNx) or silicon oxide (SiOx), for improving water and oxygen resistance of the base substrate, and a material of the semiconductor layer may be amorphous silicon (a-si).

In some exemplary embodiments, the drive circuit layer 102 may include a plurality of circuit units, and the circuit unit may at least include a pixel driving circuit, and the pixel driving circuit may include a plurality of transistors and a capacitor. The light emitting structure layer 103 may include multiple light emitting units, a light emitting unit may at least include a light emitting device, and the light emitting device may include an anode, an organic light emitting layer, and a cathode. The anode is connected to a pixel driving circuit. The organic light emitting layer is connected to the anode. The cathode is connected to the organic light emitting layer. The organic light emitting layer emits light of a corresponding color under driving of the anode and the cathode.

In some exemplary embodiments, the encapsulation structure layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is provided between the first encapsulation layer and the third encapsulation layer to form a stacked structure of inorganic material/organic material/inorganic material, which may ensure that external moisture cannot enter the light emitting structure layer 103.

In some exemplary embodiments, the organic light emitting layer may include an emitting layer (EML), and any one or more of following layers a hole injection layer (HIL), a hole transport layer (HTL), an electron block layer (EBL), a hole block layer (HBL), an electron transport layer (ETL), and an electron injection layer (EIL).

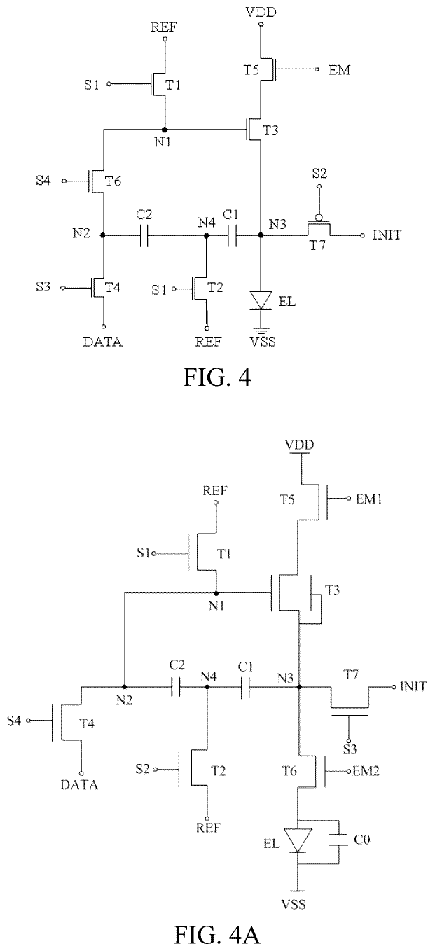

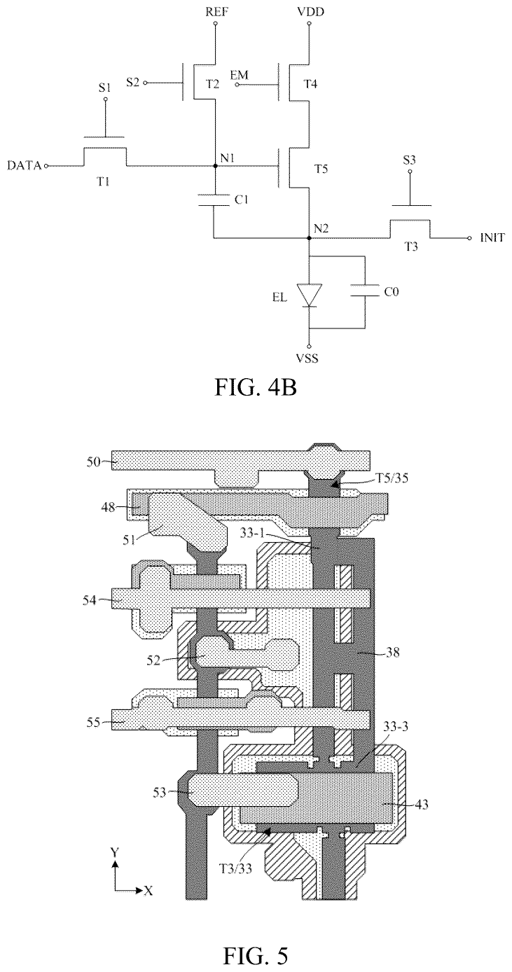

FIG. 4 is an equivalent circuit diagram of a pixel driving circuit of a display substrate according to an embodiment of the present disclosure. In an exemplary implementation, the pixel driving circuit may be of a structure of 3T1C, 4T1C, 5T1C, 5T2C, 6T1C, 7T1C, 8T1C or 9T2C. As shown in FIG. 4, the pixel driving circuit of an exemplary embodiment of the present disclosure may employ 7T2C structure. The pixel driving circuit may include seven transistors (a first transistor T1 to a seventh transistor T7) and two capacitors C. The pixel driving circuit is respectively connected to nine signal lines (a first scan signal line S1, a second scan signal line S2, a third scan signal line S3, a fourth scan signal line S4, a light emitting signal line EM, a reference signal line REF, an initial signal line INIT, a data signal line DATA and a first power supply line VDD).

In some exemplary embodiments, the pixel driving circuit may include a first node N1, a second node N2, a third node N3, and a fourth node N4. The first node N1 is respectively connected to a second electrode of the first transistor T1, a first electrode of the sixth transistor T6, and a gate electrode of the third transistor T3. The second node N2 is respectively connected to a second electrode of the fourth transistor T4, a second electrode of the sixth transistor T6, and a second end of the second capacitor C2. The third node N3 is respectively connected to a second electrode of the third transistor T3, a second electrode of the seventh transistor T7, and a second end of the first capacitor C1. The fourth node N4 is respectively connected to a second electrode of the second transistor T2, a first end of the first capacitor C1 and a first end of the second capacitor C2.

In some exemplary embodiments, the first transistor T1 may be referred to as a first reset transistor. A gate electrode of the first transistor T1 is connected to the first scan signal line S1, a first electrode of the first transistor T1 is connected to the reference signal line REF, and the second electrode of the first transistor T1 is connected to the first node N1.

In some exemplary embodiments, the second transistor T2 may be referred to as a second reset transistor. A gate electrode of the second transistor T2 is connected to the first scan signal line S1, a first electrode of the second transistor T2 is connected to the reference signal line REF, and the second electrode of the second transistor T2 is connected to the fourth node N4.

In some exemplary embodiments, the third transistor T3 may be referred to as a drive transistor. The gate electrode of the third transistor T3 is connected to the first node N1, a first electrode of the third transistor T3 is connected to the second electrode of the fifth transistor T5, and the second electrode of the third transistor T3 is connected to the third node N3.

In some exemplary embodiments, the fourth transistor T4 may be referred to as a data writing transistor. A gate electrode of the fourth transistor T4 is connected to the third scan signal line S3, a first electrode of the fourth transistor T4 is connected to a data signal line DATA, and the second electrode of the fourth transistor T4 is connected to the second node N2.

In some exemplary embodiments, the fifth transistor T5 may be referred to as a light emitting control transistor. A gate electrode of the fifth transistor T5 is connected to the light emitting signal line EM, a first electrode of the fifth transistor T5 is connected to the first power supply line VDD, and a second electrode of the fifth transistor T5 is connected to the first electrode of the third transistor T3.

In some exemplary embodiments, the sixth transistor T6 may be referred to as a data control transistor. A gate electrode of the sixth transistor T6 is connected with the fourth scan signal line S4, the first electrode of the sixth transistor T6 is connected with the first node N1, and the second electrode of the sixth transistor T6 is connected with the second node N2.

In some exemplary embodiments, the seventh transistor T7 may be referred to as a third reset transistor. A gate electrode of the seventh transistor T7 is connected to the second scan signal line S2, a first electrode of the seventh transistor T7 is connected to the initial signal line INIT, and the second electrode of the seventh transistor T7 is connected to the third node N3.

In some exemplary embodiments, a first electrode of the light emitting device EL is connected to the third node N3, and a second electrode of the light emitting device EL is connected to the second power supply line VSS. The light emitting device EL may be an OLED including a first electrode (an anode), an organic light emitting layer, and a second electrode (an cathode) which are stacked, or may be a QLED including a first electrode (an anode), a quantum dot light emitting layer, and a second electrode (a cathode) which are stacked.

In some exemplary embodiments, the seven transistors of the pixel driving circuit may be N-type transistors. Use of a same type of transistors in the pixel driving circuit may simplify a process flow, reduce process difficulties of the display substrate, and improve a yield of products.

In some exemplary embodiments, the six transistors of the pixel driving circuit may be oxide transistors. An active layer of an oxide transistor may be made of an oxide semiconductor (Oxide). Oxide transistors have the advantages of high electron mobility, low working voltage, low leakage characteristics, etc., and the use of a display substrate equipped with oxide transistors can achieve low-frequency drive, reduce power consumption and improve display quality.

In some exemplary embodiments, the first power supply line VDD may be configured to provide a constant first voltage signal to the pixel driving circuit, the second power supply line VSS may be configured to provide a constant second voltage signal to the light emitting device, and the first voltage signal is greater than the second voltage signal. The reference signal and the initial signal may be constant voltage signals, which is not limited here in the present disclosure.

FIG. 4A is an equivalent circuit diagram of a pixel driving circuit of a display substrate according to another embodiment of the present disclosure. As shown in FIG. 4A, the pixel driving circuit of an exemplary embodiment of the present disclosure may employ 7T2C structure. The pixel driving circuit may include seven transistors (a first transistor T1 to a seventh transistor T7) and two capacitors C. The pixel driving circuit is respectively connected to ten signal lines (a first scan signal line S1, a second scan signal line S2, a third scan signal line S3, a fourth scan signal line S4, a first light emitting signal line EM1, a second light emitting signal line EM2, a reference signal line REF, an initial signal line INIT, a data signal line DATA and a first power supply line VDD).

In some exemplary embodiments, the pixel driving circuit may include a first node N1, a second node N2, a third node N3, and a fourth node N4. The first node N1 is respectively connected to a second electrode of the first transistor T1 and a gate electrode of the third transistor T3. The second node N2 is respectively connected to a second electrode of the fourth transistor T4 and a second end of the second capacitor C2. The third node N3 is respectively connected to a second electrode of the third transistor T3, a second electrode of the seventh transistor T7, a second electrode of the sixth transistor T6 and a second end of the first capacitor C1. The fourth node N4 is respectively connected to a second electrode of the second transistor T2, a first end of the first capacitor C1, and a first end of the second capacitor C2.

In some exemplary embodiments, the first transistor T1 may be referred to as a first reset transistor. A gate electrode of the first transistor T1 is connected to the first scan signal line S1, a first electrode of the first transistor T1 is connected to the reference signal line REF, and the second electrode of the first transistor T1 is connected to the first node N1.

In some exemplary embodiments, the second transistor T2 may be referred to as a second reset transistor. A gate electrode of the second transistor T2 is connected to the second scan signal line S2, a first electrode of the second transistor T2 is connected to the reference signal line REF, and the second electrode of the second transistor T2 is connected to the fourth node N4.

In some exemplary embodiments, the third transistor T3 may be referred to as a drive transistor. The gate electrode of the third transistor T3 is connected to the first node N1, a first electrode of the third transistor T3 is connected to the second electrode of the fifth transistor T5, and the second electrode of the third transistor T3 is connected to the third node N3.

In some exemplary embodiments, the fourth transistor T4 may be referred to as a data writing transistor. A gate electrode of the fourth transistor T4 is connected to the fourth scan signal line S4, a first electrode of the fourth transistor T4 is connected to a data signal line DATA, and the second electrode of the fourth transistor T4 is connected to the second node N2.

In some exemplary embodiments, the fifth transistor T5 may be referred to as a first light emitting control transistor. A gate electrode of the fifth transistor T5 is connected to the first light emitting signal line EM1, a first electrode of the fifth transistor T5 is connected to the first power supply line VDD, and a second electrode of the fifth transistor T5 is connected to the first electrode of the third transistor T3.

In some exemplary embodiments, the sixth transistor T6 may be referred to as a second light emitting control transistor. A gate electrode of the sixth transistor T6 is connected to the second light emitting signal line EM2, the second electrode of the sixth transistor T6 is connected to the third node N3, and the first electrode of the sixth transistor T6 is connected to the light emitting device EL.

In some exemplary embodiments, the seventh transistor T7 may be referred to as a third reset transistor. A gate electrode of the seventh transistor T7 is connected to the third scan signal line S3, a first electrode of the seventh transistor T7 is connected to the initial signal line INIT, and the second electrode of the seventh transistor T7 is connected to the third node N3.

In some exemplary embodiments, a first electrode of the light emitting device EL is connected to a first electrode of the sixth transistor T6, and a second electrode of the light emitting device EL is connected to the second power supply line VSS. The light emitting device EL may be an OLED including a first electrode (an anode), an organic light emitting layer, and a second electrode (an cathode) which are stacked, or may be a QLED including a first electrode (an anode), a quantum dot light emitting layer, and a second electrode (a cathode) which are stacked.

FIG. 4B is an equivalent circuit diagram of a pixel driving circuit of a display substrate according to yet another embodiment of the present disclosure. As shown in FIG. 4B, the pixel driving circuit of an exemplary embodiment of the present disclosure may employ 5T1C structure. The pixel driving circuit may include five transistors (a first transistor T1 to a fifth transistor T5) and one capacitor C. The pixel driving circuit is respectively connected to eight signal lines (a first scan signal line S1, a second scan signal line S2, a third scan signal line S3, a light emitting signal line EM, a reference signal line REF, an initial signal line INIT, a data signal line DATA and a first power supply line VDD).

In some exemplary embodiments, the pixel driving circuit may include a first node N1 and a second node N2. The first node N1 is respectively connected to a second electrode of the first transistor T1, a second electrode of the second transistor T2, a gate electrode of the fifth transistor T5, and a first end of the first capacitor C1. The second node N2 is respectively connected to a second end of the first capacitor C1, a second electrode of the fifth transistor T5, a second electrode of the third transistor T3, and a first electrode of the light emitting device EL.

In some exemplary embodiments, the first transistor T1 may be referred to as a data writing transistor. A gate electrode of the first transistor T1 is connected to the first scan signal line S1, a first electrode of the first transistor T1 is connected to the data signal line DATA, and the second electrode of the first transistor T1 is connected to the first node N1.

In some exemplary embodiments, the second transistor T2 may be referred to as a first reset transistor. A gate electrode of the second transistor T2 is connected to the second scan signal line S2, a first electrode of the second transistor T2 is connected to the reference signal line REF, and the second electrode of the second transistor T2 is connected to the first node N1.

In some exemplary embodiments, the third transistor T3 may be referred to as a second reset transistor. A gate electrode of the third transistor T3 is connected to the third scan signal line S3, the second electrode of the third transistor T3 is connected to the second node N2, and a first electrode of the third transistor T3 is connected to the initial signal line INIT.

In some exemplary embodiments, the fourth transistor T4 may be referred to as a light emitting control transistor. A gate electrode of the fourth transistor T4 is connected to the light emitting signal line EM, a first electrode of the fourth transistor T4 is connected to the first power supply line VDD, and a second electrode of the fourth transistor T4 is connected to the first electrode of the fifth transistor T5.

In some exemplary embodiments, the fifth transistor T5 may be referred to as a drive transistor. The gate electrode of the fifth transistor T5 is connected to the first node N1, a first electrode of the fifth transistor T5 is connected to the second electrode of the fourth transistor T4, and the second electrode of the fifth transistor T5 is connected to the second node N2.

In some exemplary embodiments, a first electrode of the light emitting device EL is connected to the second node N2, and a second electrode of the light emitting device EL is connected to the second power supply line VSS. The light emitting device EL may be an OLED including a first electrode (an anode), an organic light emitting layer, and a second electrode (an cathode) which are stacked, or may be a QLED including a first electrode (an anode), a quantum dot light emitting layer, and a second electrode (a cathode) which are stacked.

FIG. 5 is a schematic diagram of a local planar structure of a display substrate according to an embodiment of the present disclosure. The display substrate may include a drive circuit layer disposed on a base substrate, and a light emitting structure layer disposed on a side of the drive circuit layer away from the base substrate. The drive circuit layer may at least include a plurality of circuit units, and the light emitting structure layer may at least include a plurality of light emitting units. At least one circuit unit may include a pixel driving circuit, at least one light emitting unit may include a light emitting device that may at least include an anode, an organic light emitting layer, and a cathode, and the anode in the light emitting unit is connected to a pixel driving circuit in a corresponding circuit unit. A position of an orthographic projection of a light emitting unit on the base substrate may correspond to a position of an orthographic projection of a circuit unit on the base substrate, or the position of the orthographic projection of the light emitting unit on the base substrate may not correspond to the position of the orthographic projection of the circuit unit on the base substrate.

In a plane perpendicular to the display substrate, the display substrate may include a base substrate, and a first conductive layer, a second conductive layer, a semiconductor layer, a third conductive layer, and a fourth conductive layer that are sequentially located on a side of the base substrate. The display substrate may include a compensation line 38, which may be located in the semiconductor layer. The compensation line 38 may have a straight line shape extending along a second direction Y. A first end of the compensation line 38 may be connected to a channel region 33-3 of a third active layer 33, a second end of the compensation line 38 may extend along the second direction Y, and the second end of the compensation line 38 may be connected to a second end of a first region 33-1 of the third active layer. The compensation line 38 and the first region 33-1 of the third active layer may form a parallel connection path, thereby reducing the on-resistance of the third transistor, and improving the problem of the threshold voltage divergence of the third transistor. In an embodiment of the present disclosure, the first direction X intersects with the second direction Y.

Exemplary description is made below through a manufacturing process of a display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, and the present disclosure is not limited thereto. A “thin film” refers to a layer of thin film made of a certain material on a base substrate using deposition, coating, or other processes. If the “thin film” does not need to be processed through a patterning process in the entire preparation process, the “thin film” may also be called a “layer”. If the “thin film” need to be processed through the patterning process in the entire preparation process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B. A process of manufacturing the display substrate includes following steps.

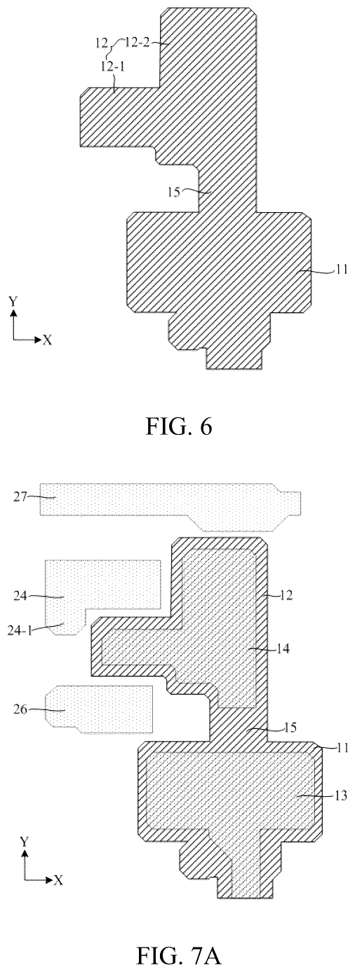

(11) Forming a pattern of a first conductive layer. Forming the pattern of the first conductive layer may include: depositing a first conductive thin film on a base substrate, and patterning the first conductive thin film by a patterning process, so as to form the pattern of the first conductive layer on the base substrate, as shown in FIG. 6. In an exemplary embodiment, the first conductive layer may be referred to as a first gate metal (GATE1) layer. The pattern of the first conductive layer may at least include a first plate 11 of a first capacitor, a second plate 12 of a second capacitor, and a plate connection block 15.

In some exemplary embodiments, the first plate 11 of the first capacitor may have a rectangular shape whose corners may be provided with chamfers or grooves, and the first plate 11 may serve as a lower plate of the first capacitor.

In some exemplary embodiments, the second plate 12 of the second capacitor may be disposed on a side of the first plate 11 in a second direction Y, a shape of the second plate 12 may be a T-shape, the corners of the T-shape may be provided with chamfers or grooves, and the second plate 12 may serve as a lower plate of the second capacitor. The second plate 12 may include a first sub-plate 12-1 and a second sub-plate 12-2 connected to each other, a shape of the first sub-plate 12-1 may be a rectangular shape extending along a first direction X, and a shape of the second sub-plate 12-2 may be a rectangular shape extending along the second direction Y. A first end of the first sub-plate 12-1 may be connected to a middle portion of the second sub-plate 12-2, for example, the middle portion may be a midpoint of the second sub-plate 12-2 along the second direction Y, and a second end of the first sub-plate 12-1 extends along an opposite direction of the first direction X. A first end of the second sub-plate 12-2 may be connected to the plate connection block 15, and a second end of the second sub-plate 12-2 extends along the second direction Y. The plate connection block 15 may have a rectangular shape extending along the second direction Y.

In some exemplary embodiments, the first plate 11 and the second plate 12 may be connected to each other to form an integral structure, that is, the lower plate of the first capacitor and the lower plate of the second capacitor may be connected to each other to form an integral structure.

In some exemplary embodiments, the first plate 11, the second plate 12, and the plate connection block 15 may be connected to each other to form an integral structure, and the plate connection block 15 may be located between the first plate 11 and the second plate 12.

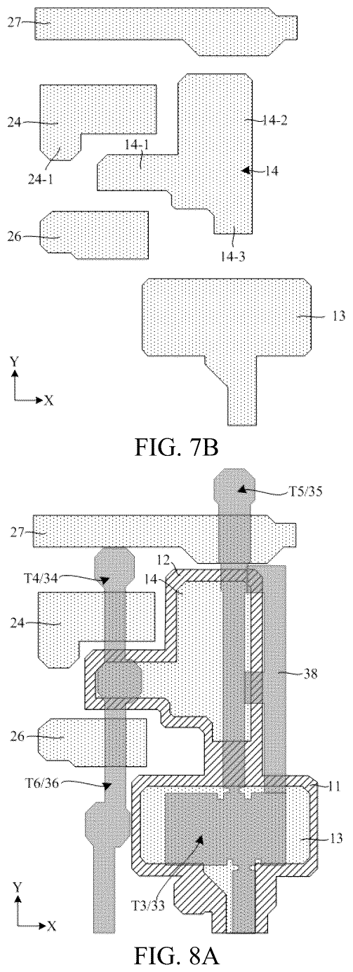

(12) Forming a pattern of a second conductive layer. Forming the pattern of the second conductive layer may include: depositing sequentially a first insulating thin film and a second conductive thin film on the base substrate on which the aforementioned patterns are formed, and patterning the second conductive thin film through a patterning process to form a first insulating layer that covers the pattern of the first conductive layer, and the pattern of the second conductive layer disposed on the first insulating layer, as shown in FIG. 7A and FIG. 7B. FIG. 7B is a schematic plan view of the second conductive layer in FIG. 7A. In an exemplary implementation, the second conductive layer may be referred to as a second gate metal (GATE2) layer.

In some exemplary embodiments, the pattern of the second conductive layer in the display substrate may at least include a third plate 13 of the first capacitor, a fourth plate 14 of the second capacitor, a fourth bottom gate electrode 24, a sixth bottom gate electrode 26, and a shielding line 27.

In some exemplary embodiments, the third plate 13 of the first capacitor may have a rectangular shape, and the corners of the rectangular shape may be provided with chamfers or grooves. An orthographic projection of the third plate 13 of the first capacitor on the base substrate may at least partially overlap with an orthographic projection of the first plate 11 of the first capacitor on the base substrate. For example, the orthographic projection of the third plate 13 on the base substrate may be within the orthographic projection of the first plate 11 on the base substrate. The third plate 13 may serve as an upper plate of the first capacitor, and the first plate 11 and the third plate 13 may jointly form the first capacitor. In some exemplary embodiments, the fourth plate 14 of the second capacitor may be disposed on a side of the third plate 13 in the second direction Y. An orthographic projection of the fourth plate 14 on the base substrate may at least partially overlap with an orthographic projection of the second plate 12 on the base substrate. For example, the orthographic projection of the fourth plate 14 on the base substrate may be within the orthographic projection of the second plate 12 on the base substrate. In an exemplary embodiment, the second plate 12 and the fourth plate 14 may jointly form the second capacitor.

In some exemplary embodiments, the fourth plate 14 may include a first sub-block 14-1, a second sub-block 14-2, and a third sub-block 14-3 connected to each other. The first sub-block 14-1 may have a rectangular shape extending along the first direction X, the second sub-block 14-2 may have a rectangular shape extending along the second direction Y, and the third sub-block 14-3 may have a rectangular shape extending along the second direction Y. A first end of the first sub-block 14-1 may be connected to a middle portion of the second sub-block 14-2, for example, the middle portion may be a center of the second sub-block 14-2 in the second direction Y, and a second end of the first sub-block 14-1 may extend along the opposite direction of the first direction X. A first end of the third sub-block 14-3 may be connected a the first end of the second sub-block 14-2, and a second end of the third sub-block 14-3 may extend along the opposite direction of the second direction Y, and a second end of the second sub-block 14-2 may extend along the second direction Y.

In some exemplary embodiments, the fourth bottom gate electrode 24 may have rectangular shape. The fourth bottom gate electrode 24 may be disposed on a side of the second sub-block 14-2 in the opposite direction of the first direction X. The fourth bottom gate electrode 24 may serve as a bottom gate electrode of the fourth transistor T4 and may serve as a shielding layer of the fourth transistor T4, and may be used to shield the channel region of the fourth transistor T4, thereby ensuring the electrical performance of the fourth transistor T4.

In some exemplary embodiments, a fourth bottom gate connection block 24-1 may be provided on the fourth bottom gate electrode 24. A shape of the fourth bottom gate connection block 24-1 may be a block shape (e.g., a rectangle), and the fourth bottom gate connection block 24-1 may be disposed on a side of the fourth bottom gate electrode 24 close to the sixth bottom gate electrode 26, and is connected to the fourth bottom gate electrode 24. The fourth bottom gate connection block 24-1 may be configured to be connected to the third scan signal line formed subsequently.

In some exemplary embodiments, the sixth bottom gate electrode 26 may have a rectangular shape, and may be disposed on a side of the first sub-block 14-1 in the opposite direction of the second direction Y, and located on a side of the fourth bottom gate electrode 24 in the opposite direction of the second direction Y. The sixth bottom gate electrode 26 may serve as a bottom gate electrode of the sixth transistor T6, and may serve as a shielding layer of the sixth transistor T6, and may be used to shield the channel region of the sixth transistor T6, thereby ensuring the electrical performance of the sixth transistor T6.

In some exemplary embodiments, a shape of the shielding line 27 may be a straight line shape or a polyline shape extending along the first direction X, and the shielding line 27 may be disposed on a side of the fourth plate 14 away from the third plate 13. In some exemplary embodiments, the shielding line 27 may be a straight line with non-uniform width, and a width at a position where the shielding line 27 overlaps with a fifth active layer formed subsequently may be greater than widths at other positions. The shielding line 27 at a wider position may serve as a shielding layer of the fifth transistor T5 and may be used to shield the channel region of the fifth transistor T5, and may ensure the electrical performance of the fifth transistor T5. In some possible exemplary implementations, the shielding line 27 may serve as the bottom gate electrode of the fifth transistor T5.

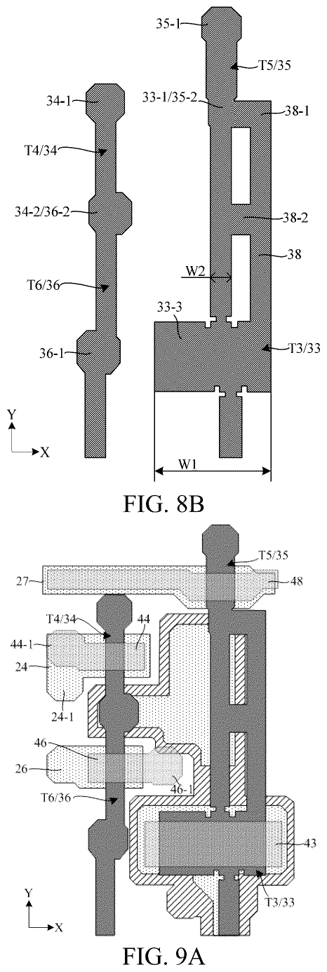

(13) Forming a pattern of a semiconductor layer. Forming the pattern of the semiconductor layer may include: depositing sequentially a second insulating thin film and a semiconductor thin film on the base substrate on which the aforementioned patterns are formed, and patterning the semiconductor thin film through a patterning process to form a second insulating layer covering the second conductive layer, and the pattern of the semiconductor layer disposed on the second insulating layer, as shown in FIG. 8A and FIG. 8B. FIG. 8B is a schematic plan view of the semiconductor layer in FIG. 8A.

In some exemplary embodiments, the pattern of the semiconductor layer in the display substrate may at least include a third active layer 33 of the third transistor T3 to a sixth active layer 36 of the sixth transistor T6. The third active layer 33 and the fifth active layer 35 may connected to each other to form an integral structure, and the fourth active layer 34 and the sixth active layer 36 may be connected to each other to form an integral structure. In the first direction X, the fourth active layer 34 and the sixth active layer 36 may be located on a side of the third active layer 33 and the fifth active layer 35 in the opposite direction of the first direction X. The fourth active layer 34 may be located on a side of the sixth active layer 36 in the second direction Y, and the fifth active layer 35 may be located on a side of the third active layer 33 in the second direction Y. In some exemplary embodiments, an active layer of each transistor may include a first region, a second region, and a channel region located between the first region and the second region. An orthographic projection of the third active layer 33 on the base substrate may at least partially overlap with an orthographic projection of the third plate 13 on the base substrate, and the overlapping region may serve as the channel region of the third transistor T3. An orthographic projection of the fourth active layer 34 on the base substrate may at least partially overlap with an orthographic projection of the fourth bottom gate electrode 24 on the base substrate, and the overlapping region serves as the channel region of the fourth transistor T4. An orthographic projection of the fifth active layer 35 on the base substrate may at least partially overlap with an orthographic projection of the shielding line 27 on the base substrate, and the overlapping region serves as the channel region of the fifth transistor T5. In some exemplary implementations, an orthographic projection of the sixth active layer 36 on the base substrate may at least partially overlap with an orthographic projection of the sixth bottom gate electrode 26 on the base substrate, and the overlapping region serves the channel region of the sixth transistor T6.

In some exemplary embodiments, a first region 33-1 of the third active layer and a second region 35-2 of the fifth active layer may be connected with each other, and the first region 33-1 of the third active layer may serve as the second region 35-2 of the fifth active layer. A second region 34-2 of the fourth active layer 34 and a second region 36-2 of the sixth active layer 36 may be connected with each other, and the second region 34-2 of the fourth active layer may serve as the second region 36-2 of the sixth active layer. A first region 34-1 of the fourth active layer 34 and a first region 35-1 of the fifth active layer 35 may be separately disposed. A first region 36-1 of the sixth active layer and a second region 36-2 of the sixth active layer are respectively located on two sides of the channel region of the sixth active layer along the second direction Y.

In some exemplary embodiments, the channel region 33-3 of the third active layer may have a rectangular shape, and the corners of the rectangular shape may be provided with chamfers or grooves. The channel region 33-3 of the third active layer has a first width W1 along the first direction X. In an embodiment of the present disclosure, the first width W1 is an average width of the channel region 33-3 of the third active layer along the first direction X. The first region 33-1 of the third active layer is located on a side of the channel region 33-3 of the third active layer in the second direction Y, a first end of the first region 33-1 of the third active layer is connected to the channel region 33-3 of the third active layer, and a second end of the first region 33-1 of the third active layer extends along the second direction Y. The first region 33-1 of the third active layer has a second width W2 along the first direction X. In an embodiment of the present disclosure, the second width W2 is an average width of the first region 33-1 of the third active layer along the first direction X. An absolute value of a difference between the first width W1 and the second width W2 is less than or equal to 10% of the first width W1. By limiting the difference between the first width W1 and the second width W2, the problem of the threshold voltage divergence of the third transistor can be avoided, and the operational performance of the third transistor can be improved. In some examples, the first region of the third active layer and the second region of the third active layer may be interchanged.

As shown in Table 1 below, a plurality of performance parameters of two types of pixel driving circuits are compared. In the embodiment of the present disclosure, W1 equal to W2 represents that the first width W1 is equal to the second width W2 in the pixel driving circuit, or the absolute value of the difference between the first width W1 and the second width W2 is greater than zero and less than or equal to 10% of the first width W1, that is, W1 equal to W2 in Table 1 represents that they are approximately equal. In the embodiment of the present disclosure, W1 not equal to W2 represents that the absolute value of the difference between the first width W1 and the second width W2 in the pixel driving circuit is greater than 10% of the first width W1.

TABLE 1

| | W1 not equal to W2 | W1 equal to W2 |
|---|---|---|
| Saturation Region | 5.51 | 0.99 |
| Threshold Voltage | | |
| (VTH_SAT) | | |
| Saturation Region | 10.77 | 2.88 |
| Threshold Voltage | | |
| (VTH_SAT 36) | | |
| Electron Mobility | 0.11 | 4.31 |
| (Mob) | | |
| Electron Mobility | 0.09 | 5.36 |
| (Mob 36) | | |
| On-state Current (Ion) | 2.84E−08 | 3.91E−06 |
| Average | | |
| On-state Current | 7.32E−10 | 1.81E−08 |
| Minimum (Ion Min) | | |
| On-state Current | 98.2% | 99.5% |
| Uniformity (Ion U %) | | |

As shown in Table 1 above, the pixel driving circuit in which W1 is equal to W2 has better performance than the pixel driving circuit in which W1 is not equal to W2. The second width W2 is relatively small, and the corresponding line resistance is large. When the third transistor is turned on, the current needs to pass through a channel with a relatively large line resistance. Due to the blocking effect of the channel, the number of carriers decreases, the turning on between the first region and the second region in the third transistor is not easy, the threshold voltage shifts positively, and the electron mobility (Mob) and the on-state current (Ion) decrease. The second width W2 is relatively large, and the corresponding line resistance is small. When the third transistor is turned on, the current needs to pass through a channel with a relatively small line resistance. Since the blocking effect of the channel is relatively reduced, the number of carriers is less affected, the turning on between the first region and the second region in the third transistor is easy, the threshold voltage is slightly negatively shifted, and the electron mobility (Mob) and the on-state current (Ion) are improved. According to Table 1, the electron mobility (Mob) is improved from 0.11 to 4.31, and the average of on-state current (Ion) is improved two orders of magnitude.

In some exemplary embodiments, the first region 33-1 of the third active layer and the second region of the third active layer may be symmetrical with respect to the channel region 33-3 of the third active layer.

In some exemplary embodiments, the pattern of the semiconductor layer in the display substrate may include a compensation line 38, and the compensation line 38 may have a straight line shape extending along the second direction Y. The compensation line 38 is located on a side of the channel region 33-3 of the third active layer 33 in the second direction Y. A first end of the compensation line 38 may be connected to the channel region 33-3 of the third active layer 33, a second end of the compensation line 38 extends along the second direction Y, and the second end of the compensation line 38 is connected to a second end of the first region 33-1 of the third active layer. The compensation line 38 and the first region 33-1 of the third active layer may form a parallel connection path, thereby reducing the on-resistance of the third transistor, and improving the problem of the threshold voltage divergence of the third transistor.

In some exemplary embodiments, an orthographic projection of the compensation line 38 on the base substrate does not overlap with an orthographic projection of the fourth plate 14 on the base substrate, and the orthographic projection of the compensation line 38 on the base substrate does not overlap with an orthographic projection of the second plate 12 on the base substrate. In this way, the adverse effect caused by the step difference formed at edges of the fourth plate and the second plate on the compensation line can be avoided, the breakage of the compensation line at the step formed at the edges of the fourth plate and the second plate can be avoided, and the performance stability of the pixel driving circuit can be improved.

In some exemplary embodiments, the pattern of the semiconductor layer in the display substrate may further include a first connection bridge 38-1. The first connection bridge 38-1 may have a rectangular shape extending along the first direction X, a first end of the first connection bridge 38-1 may be connected to the second end of the compensation line 38, a second end of the first connection bridge 38-1 may extend along the opposite direction of the first direction X, and the second end of the first connection bridge 38-1 may be connected to the second end of the first region 33-1 of the third active layer.

In some exemplary embodiments, the pattern of the semiconductor layer in the display substrate may further include a second connection bridge 38-2. The second connection bridge 38-2 may be located between the first connection bridge 38-1 and the channel region 33-3 of the third active layer 33, and the second connection bridge 38-2 may be located between the first region 33-1 of the third active layer and the compensation line 38. The second connection bridge 38-2 may have a rectangular shape, a first end of the second connection bridge 38-2 may be connected to the compensation line 38, a second end of the second connection bridge 38-2 may extend along the opposite direction of the first direction X, and the second end of the second connection bridge 38-2 may be connected to the first region 33-1 of the third active layer.

In some possible exemplary embodiments, the pattern of the semiconductor layer in the display substrate may further include a plurality of second connection bridges 38-2. The plurality of second connection bridges 38-2 may be arranged at intervals along the second direction Y. For example, the plurality of second connection bridges 38-2 may be arranged at equal intervals along the second direction Y. In an embodiment of the present disclosure, by providing a plurality of second connection bridges, reliability of connection between the compensation line and the first region of the third active layer can be improved.

In some possible exemplary embodiments, the pattern of the semiconductor layer in the display substrate may at least include a third active layer 33 of the third transistor T3, a fourth active layer 34 of the fourth transistor T4, and a fifth active layer 35 of the fifth transistor T5. The third active layer 33 and the fifth active layer 35 may be connected with each other to form an integral structure. In the first direction X, the fourth active layer 34 may be located on a side of the third active layer 33 and the fifth active layer 35 in the opposite direction of the first direction X. The fifth active layer 35 may be located on a side of the third active layer 33 in the second direction Y.

In some exemplary embodiments, the semiconductor layer may be made of an oxide, i.e., the third transistor T3 to the sixth transistor T6 are oxide transistors. Oxide transistors have advantages of high electron mobility, low working voltage, low leakage characteristics, etc. The oxide may be any one or more of Indium Gallium Zinc Oxide (InGaZnO), Indium Gallium Zinc Oxynitride (InGaZnON), Zinc Oxide (ZnO), Zinc Oxynitride (ZnON), Zinc Tin Oxide (ZnSnO), Cadmium Tin Oxide (CdSnO), Gallium Tin Oxide (GaSnO), Titanium Tin Oxide (TiSnO), Copper Aluminum Oxide (CuAlO), Strontium Copper Oxide (SrCuO), Lanthanum Copper Oxysulfide (LaCuOS), Gallium Nitride (GaN), Indium Gallium Nitride (InGaN), Aluminum Gallium Nitride (AlGaN), Indium Gallium Zinc Oxide (IGZO), and Indium Gallium Aluminum Nitride (InGaAlN).

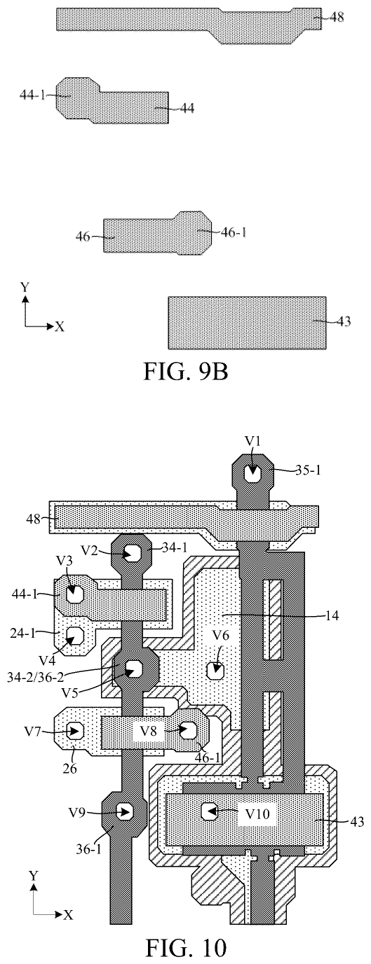

(14) Forming a pattern of a third conductive layer. Forming the pattern of the third conductive layer may include: depositing sequentially a third insulating thin film and a third conductive thin film on the base substrate on which the aforementioned patterns are formed, and patterning the third conductive thin film through a patterning process to form a third insulating layer that covers the pattern of the semiconductor layer, and the pattern of the third conductive layer disposed on the third insulating layer, as shown in FIG. 9A and FIG. 9B. FIG. 9B is a schematic plan view of the third conductive layer in FIG. 9A. In an exemplary embodiment, the third conductive layer may be referred to as a third gate metal (GATE3) layer.

In some exemplary embodiments, the pattern of the third conductive layer in the display substrate may at least include a third top gate electrode 43, a fourth top gate electrode 44, a sixth top gate electrode 46, and a light emitting signal line 48.

In some exemplary embodiments, the third top gate electrode 43 may have a rectangular shape extending along the first direction X, and an orthographic projection of the third top gate electrode 43 on the base substrate may at least partially overlap with an orthographic projection of the third active layer 33 on the base substrate. The third top gate electrode 43 may serve as a top gate electrode of the third transistor T3.

In some exemplary embodiments, the fourth top gate electrode 44 may have a rectangular shape, an orthographic projection of the fourth gate electrode 44 on the base substrate at least partially overlaps with an orthographic projection of the fourth active layer 34 on the base substrate, and the fourth top gate electrode 44 may serve as a top gate electrode of the fourth transistor T4. The orthographic projection of the fourth top gate electrode 44 on the base substrate at least partially overlaps with the orthographic projection of the fourth bottom gate electrode 24 on the base substrate, and the fourth top gate electrode 44 and the fourth bottom gate electrode 24 form the fourth transistor T4 with a structure having top gate and bottom gate.

In some exemplary embodiments, a fourth top gate connection block 44-1 may be provided on the fourth top gate electrode 44. A shape of the fourth top gate connection block 44-1 may be a block shape, for example, a rectangular block shape, a hexagonal block shape, or the like. The fourth top gate connection block 44-1 may be disposed on a side of the fourth top gate electrode 44 away from the fifth transistor T5, and the fourth top gate connection block 44-1 is connected to the fourth top gate electrode 44. The fourth top gate connection block 44-1 is configured to be connected to a third scan signal line formed subsequently.

In some exemplary embodiments, the sixth top gate electrode 46 may have a rectangular shape, an orthographic projection of the sixth top gate electrode 46 on the base substrate at least partially overlaps with an orthographic projection of the sixth active layer 36 on the base substrate, and the sixth top gate electrode 46 may serve as a top gate electrode of the sixth transistor T6. The orthographic projection of the sixth top gate electrode 46 on the base substrate at least partially overlaps the orthographic projection of the sixth bottom gate electrode 26 on the base substrate, and the sixth top gate electrode 46 and the sixth bottom gate electrode 26 form the sixth transistor T6 with a structure have top gate and bottom gate.

In some exemplary embodiments, a sixth top gate connection block 46-1 may be provided on the sixth top gate electrode 46. A shape of the sixth top gate connection block 46-1 may be a block shape, for example, a rectangular block shape, a hexagonal block shape, or the like. The sixth top gate connection block 46-1 may be disposed on a side of the sixth top gate electrode 46 close to the third transistor T3, and the sixth top gate connection block 46-1 is connected to the sixth top gate electrode 46. The sixth top gate connection block 46-1 is configured to be connected to a fourth scan signal line formed subsequently.

In some exemplary embodiments, the shape of the light emitting signal line 48 may be a straight line shape or a polyline shape extending along the first direction X. The light emitting signal line 48 may be disposed on a side of the fourth plate 14 in the second direction Y, the light emitting signal line 48 may at least partially overlap with the fifth active layer 35, and the overlapping region may serve as a top gate electrode of the fifth transistor T5.

In some exemplary embodiments, the light emitting signal line 48 may be a straight line with non-uniform width, and a width at the position where the light emitting signal line 48 overlaps with the fifth active layer 35 may be larger than widths at other positions. An orthographic projection of the light emitting signal line 48 on the base substrate at least partially overlaps with an orthographic projection of the shielding line 27 on the base substrate. The light emitting signal line 48 and the shielding line 27 may be connected with a same signal source, so that the shielding line 27 may serve as a bottom gate electrode of the fifth transistor T5, and the light emitting signal line 48 may serve as a top gate electrode of the fifth transistor T5, thereby forming the second transistor T5 with a structure having top gate and bottom gate.

In some exemplary embodiments, after the pattern of the third conductive layer is formed, a conductorization treatment may be performed on the semiconductor layer by using the third conductive layer as a shield. The semiconductor layer in the region shielded by the third conductive layer forms channel regions of the third transistor T3 to the sixth transistor T6, and the semiconductor layer in the region not shielded by the third conductive layer undergoes conductorization.

(15) Forming a pattern of a fourth insulating layer. Forming the pattern of the fourth insulating layer may include: depositing a fourth insulating thin film on the base substrate on which the above-mentioned patterns are formed, and patterning the fourth insulating thin film through a patterning process to form a fourth insulating layer covering the third conductive layer. The fourth insulating layer is provided with a plurality of vias, as shown in FIG. 10.

In some exemplary embodiments, the plurality of vias in the display substrate may at least include a first via V1, a second via V2, a third via V3, a fourth via V4, a fifth via V5, a sixth via V6, a seventh via V7, an eighth via V8, a ninth via V9 and a tenth via V10.

In some exemplary embodiments, an orthographic projection of the first via V1 on the base substrate may be within a range of an orthographic projection of the first region 35-1 of the fifth active layer on the base substrate. The third insulating layer and the fourth insulating layer in the first via V1 are etched away and a surface of the first region 35-1 of the fifth active layer is exposed. The first via V1 is configured such that a power supply connection line formed subsequently may be connected with the first region 35-1 of the fifth active layer through this via.

In some exemplary embodiments, an orthographic projection of the second via V2 on the base substrate may be within a range of an orthographic projection of the first region 34-1 of the fourth active layer on the base substrate, the third insulating layer and the fourth insulating layer in the second via V2 are etched away, and a surface of the first region 34-1 of the fourth active layer is exposed. The second via V2 is configured such that a first connection electrode formed subsequently may be connected with the first region 34-1 of the fourth active layer through this via.

In some exemplary embodiments, an orthographic projection of the third via V3 on the base substrate may be within a range of an orthographic projection of the fourth top gate connection block 44-1 on the base substrate. The fourth insulating layer in the third via V3 is etched away, and a surface of the fourth top gate connection block 44-1 is exposed. The third via V3 is configured such that a third scan signal line formed subsequently may be connected with the fourth top gate connection block 44-1 through this via.

In some exemplary embodiments, an orthographic projection of the fourth via V4 on the base substrate may be within a range of an orthographic projection of the fourth bottom gate connection block 24-1 on the base substrate. The second insulating layer, the third insulating layer, and the fourth insulating layer within the fourth via V4 are all etched away, and a surface of the fourth bottom gate connection block 24-1 is exposed. The fourth via V4 is configured such that a third scan signal line formed subsequently may be connected with the fourth bottom gate connection block 24-1 through this via.

In some exemplary embodiments, an orthographic projection of the fifth via V5 on the base substrate may be within a range of an orthographic projection of the second region 36-2 of the sixth active layer (also the second region 34-2 of the fourth active layer) on the base substrate. The third insulating layer and the fourth insulating layer within the fifth via V5 are etched away, and a surface of the second region 36-2 of the sixth active layer (also the second region 34-2 of the fourth active layer) is exposed. The fifth via V5 is configured such that a second connection electrode subsequently formed may be connected with the second region 36-2 of the sixth active layer (also the second region 34-2 of the fourth active layer) through this via.

In some exemplary embodiments, an orthographic projection of the sixth via V6 on the base substrate may be within a range of an orthographic projection of the fourth plate 14 on the base substrate. The second insulating layer, the third insulating layer, and the fourth insulating layer within the sixth via V6 are all etched away, and a surface of the fourth plate 14 is exposed. The six via V6 is configured such that a second connection electrode formed subsequently may be connected with the fourth plate 14 through this via.

In some exemplary embodiments, an orthographic projection of the seventh via V7 on the base substrate may be within a range of an orthographic projection of the sixth bottom gate electrode 26 on the base substrate. The second insulating layer, the third insulating layer, and the fourth insulating layer within the seventh via V7 are all etched away, and a surface of the sixth bottom gate electrode 26 is exposed. The seventh via V7 is configured such that a fourth scan signal line formed subsequently may be connected with the sixth bottom gate electrode 26 through this via.

In some exemplary embodiments, an orthographic projection of the eighth via V8 on the base substrate may be within a range of an orthographic projection of the sixth top gate connection block 46-1 on the base substrate. The fourth insulating layer in the eighth via V8 is etched away, and a surface of the sixth top gate connection block 46-1 is exposed. The eighth via V8 is configured such that a fourth scan signal line formed subsequently may be connected with the sixth top gate connection block 46-1 through this via.

In some exemplary embodiments, an orthographic projection of the ninth via V9 on the base substrate may be within a range of an orthographic projection of the first region 36-1 of the sixth active layer on the base substrate. The third insulating layer and the fourth insulating layer in the ninth via V9 are etched away, and a surface of the first region 36-1 of the sixth active layer is exposed. The ninth via V9 is configured such that a third connection electrode formed subsequently may be connected with the first region 36-1 of the sixth active layer through this via.

In some exemplary embodiments, an orthographic projection of the tenth via V10 on the base substrate may be within a range of an orthographic projection of the third top gate electrode 43 on the base substrate. The fourth insulating layer in the tenth via V10 is etched away, and a surface of the third top gate electrode 43 is exposed. The tenth via V10 is configured such that a third connection electrode formed subsequently may be connected with the third top gate electrode 43 through this via.

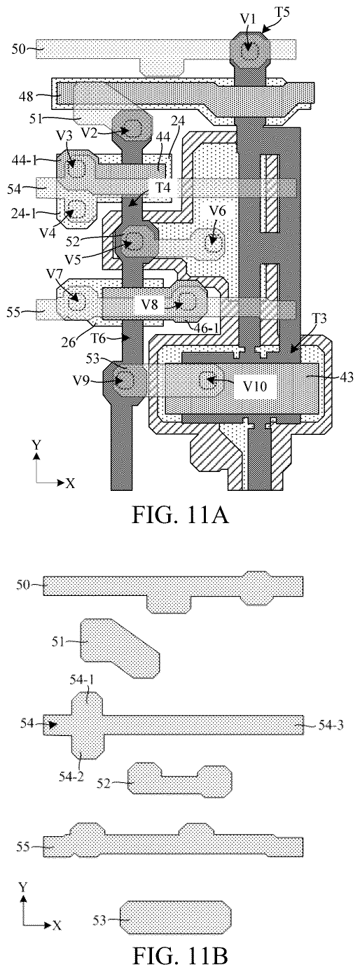

(16) Forming a pattern of a fourth conductive layer. Forming the pattern of the fourth conductive layer may include: depositing a fourth conductive thin film on the base substrate on which the above-mentioned patterns are formed, and patterning the fourth conductive thin film through a patterning process to form the fourth conductive layer disposed on the fourth insulating layer, as shown in FIGS. 11A and 11B. FIG. 11B is a schematic plan view of the fourth conductive layer in FIG. 11A. In an exemplary embodiment, the fourth conductive layer may be referred to as a first source-drain metal (SD1) layer.

In some exemplary embodiments, the fourth conductive layer may at least include a power supply connection line 50, a first connection electrode 51, a second connection electrode 52, a third connection electrode 53, a third scan signal line 54, and a fourth scan signal line 55.

In some exemplary embodiments, the power supply connection line 50 may be located on a side of the light emitting signal line 48 in the second direction Y. A shape of the power supply connection line 50 may be a straight line shape or a polyline shape extending along the first direction X. An orthographic projection of the power supply connection line 50 on the base substrate may at least partially overlap with an orthographic projection of the first region of the fifth active layer on the base substrate, the orthographic projection of the power supply connection line 50 on the base substrate may include an orthographic projection of the first via V1 on the base substrate, and the power supply connection line 50 may be connected to the first region of the fifth active layer through the first via V1.

In some exemplary embodiments, the first connection electrode 51 may be located between the power supply connection line 50 and the fourth top gate connection block 44-1. A shape of the first connection electrode 51 may be a rectangular shape. An orthographic projection of the first connection electrode 51 on the base substrate may partially overlap with an orthographic projection of the light emitting signal line 48 on the base substrate. The orthographic projection of the first connection electrode 51 on the base substrate may partially overlap with an orthographic projection of the first region of the fourth active layer on the base substrate. The orthographic projection of the first connection electrode 51 on the base substrate may include an orthographic projection of the second via V2 on the base substrate, and the first connection electrode 51 may be connected to the first region of the fourth active layer through the second via V2.

In some exemplary embodiments, the third scan signal line 54 may be located on a side of the first connection electrode 51 in the opposite direction of the second direction Y. An orthographic projection of the third scan signal line 54 on the base substrate at least partially overlaps with orthographic projections of the fourth top gate connection block 44-1 and the fourth bottom gate connection block 24-1 on the base substrate. On one hand, the third scan signal line 54 is connected to the fourth top gate connection block 44-1 through the third via V3, and on the other hand, the third scan signal line 54 is connected to the fourth bottom gate connection block 24-1 through the fourth via V4. Since the fourth top gate connection block 44-1 is connected to the fourth top gate electrode 44 and the fourth bottom gate connection block 24-1 is connected to the fourth bottom gate electrode 24, the third scan signal line 54 is simultaneously connected to the bottom gate electrode of the fourth transistor T4 and the top gate electrode of the fourth transistor T4, and the third scan signal line 54 can control the on or off of the fourth transistor T4.

In some exemplary embodiments, the third scan signal line 54 may include a first connection block 54-1, a second connection block 54-2, and a body portion 54-3 connected to each other. The body portion 54-3 may have a straight line shape extending along the first direction X, a first end of the first connection block 54-1 may be connected to the body portion 54-3, and a second end of the first connection block 54-1 may extend along the second direction Y. An orthographic projection of the first connection block 54-1 on the base substrate may include an orthographic projection of the third via V3 on the base substrate, and the first connection block 54-1 may be connected to the fourth top gate connection block 44-1 through the third via V3. A first end of the second connection block 54-2 may be connected to the body portion 54-3, and a second end of the second connection block 54-2 may extend along the opposite direction of the second direction Y. An orthographic projection of the second connection block 54-2 on the base substrate may include an orthographic projection of the fourth via V4 on the base substrate, and the second connection block 54-2 may be connected to the fourth bottom gate connection block 24-1 through the fourth via V4.

In some exemplary embodiments, a shape of the second connection electrode 52 may be a rectangular shape, and the second connection electrode 52 may be located on a side of the third scan signal line 54 in the opposite direction of the second direction Y. An orthographic projection of the second connection electrode 52 on the base substrate may include an orthographic projection of the fifth via V5 on the base substrate, and the orthographic projection of the second connection electrode 52 on the base substrate may include an orthographic projection of the sixth via V6 on the base substrate. The second connection electrode 52 may be connected to the second region of the sixth active layer through the fifth via V5, and the second connection electrode 52 may be connected to the fourth plate through the sixth via V6.

In some exemplary embodiments, a shape of the fourth scan signal line 55 may be a straight line shape or a polyline shape extending along the first direction X. The fourth scan signal line 55 may be located on a side of the second connection electrode 52 in the opposite direction of the second direction Y. An orthographic projection of the fourth scan signal line 55 on the base substrate at least partially overlaps orthographic projections of the sixth top gate connection block 46-1 and the sixth bottom gate electrode 26 on the base substrate. On one hand, the fourth scan signal line 55 is connected to the sixth bottom gate electrode 26 through the seventh via V7, and on the other hand, the fourth scan signal line 55 is connected to the sixth top gate connection block 46-1 through the eighth via V8. Since the sixth top gate connection block 46-1 is connected to the sixth top gate electrode 46, the fourth scan signal line 55 is simultaneously connected to the bottom gate electrode of the sixth transistor T6 and the top gate electrode of the sixth transistor T6, and the fourth scan signal line 55 can control the on or off of the sixth transistor T6.

In some exemplary embodiments, a shape of the third connection electrode 53 may be a rectangular shape, and the third connection electrode 53 may be located on a side of the fourth scan signal line 55 in the opposite direction of the second direction Y. An orthographic projection of the third connection electrode 53 on the base substrate may include an orthographic projection of the ninth via V9 on the base substrate, and the orthographic projection of the third connection electrode 53 on the base substrate may include an orthographic projection of the tenth via V10 on the base substrate. The third connection electrode 53 may be connected to the first region of the sixth active layer through the ninth via V9, and the third connection electrode 53 may be connected to the third top gate electrode through the tenth via V10.

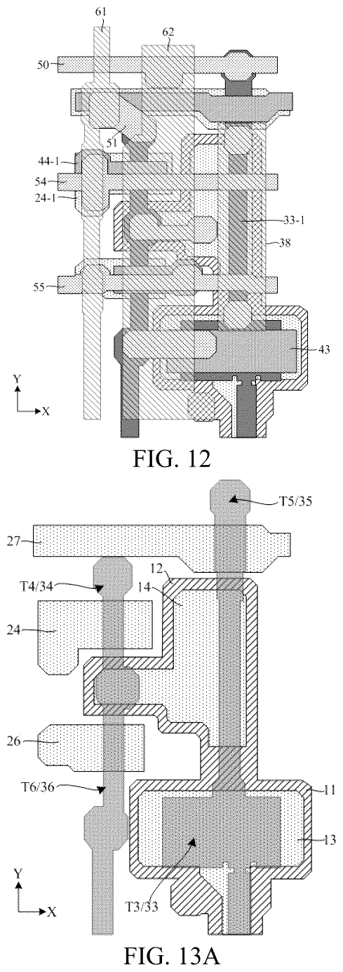

FIG. 12 is a schematic diagram of a local planar structure of a display substrate according to another embodiment of the present disclosure. In a plane perpendicular to the display substrate, the display substrate may include a base substrate and a first conductive layer, a second conductive layer, a semiconductor layer, a third conductive layer, a fourth conductive layer, and a fifth conductive layer that are sequentially located on a side of the base substrate. The compensation line 38 may be located in the fifth conductive layer, and an orthographic projection of the compensation line 38 on the base substrate may include an orthographic projection of the first region 33-1 of the third active layer on the base substrate. The compensation line 38 and the first region 33-1 of the third active layer may form a parallel connection path, thereby reducing the on-resistance of the third transistor, and improving the problem of the threshold voltage divergence of the third transistor.

A process of manufacturing the display substrate includes following steps.

(21) Sequentially forming a pattern of a first conductive layer and a pattern of a second conductive layer on a base substrate. This step may be described with reference to the foregoing embodiments, which will not be described in detail herein.

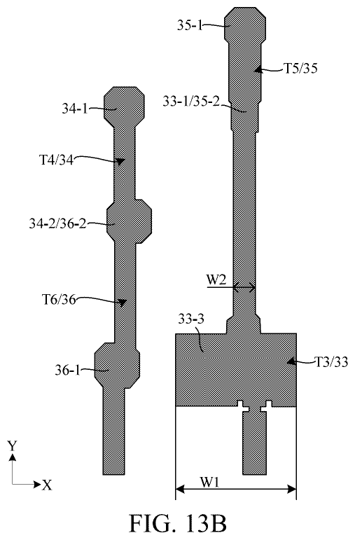

(22) Forming a pattern of a semiconductor layer. Forming the pattern of the semiconductor layer may include: depositing sequentially a second insulating thin film and a semiconductor thin film on the base substrate on which the aforementioned patterns are formed, and patterning the semiconductor thin film through a patterning process to form a second insulating layer covering the second conductive layer, and the pattern of the semiconductor layer disposed on the second insulating layer, as shown in FIG. 13A and FIG. 13B. FIG. 13B is a schematic plan view of the semiconductor layer in FIG. 13A.

In some exemplary embodiments, the pattern of the semiconductor layer in the display substrate may at least include a third active layer 33 of the third transistor T3 to a sixth active layer 36 of the sixth transistor T6. The third active layer 33 and the fifth active layer 35 may be connected to each other to form an integral structure, and the fourth active layer 34 and the sixth active layer 36 may be connected to each other to form an integral structure. In the first direction X, the fourth active layer 34 and the sixth active layer 36 may be located on a side of the third active layer 33 and the fifth active layer 35 in opposite direction of the first direction X. The fourth active layer 34 may be located on a side of the sixth active layer 36 in the second direction Y, and the fifth active layer 35 may be located on a side of the third active layer 33 in the second direction Y.

In some exemplary embodiments, an active layer of each transistor may include a first region, a second region, and a channel region located between the first region and the second region. An orthographic projection of the third active layer 33 on the base substrate may at least partially overlap with an orthographic projection of the third plate 13 on the base substrate, and the overlapping region may serve as the channel region of the third transistor T3. An orthographic projection of the fourth active layer 34 on the base substrate may at least partially overlap with an orthographic projection of the fourth bottom gate electrode 24 on the base substrate, and the overlapping region serves as the channel region of the fourth transistor T4. An orthographic projection of the fifth active layer 35 on the base substrate may at least partially overlap with an orthographic projection of the shielding line 27 on the base substrate, and the overlapping region serves as the channel region of the fifth transistor T5. An orthographic projection of the sixth active layer 36 on the base substrate may at least partially overlap with an orthographic projection of the sixth bottom gate electrode 26 on the base substrate, and the overlapping region serves as the channel region of the sixth transistor T6.

In some exemplary embodiments, a first region 33-1 of the third active layer and a second region 35-2 of the fifth active layer may be connected with each other, and the first region 33-1 of the third active layer may serve as the second region 35-2 of the fifth active layer. A second region 34-2 of the fourth active layer and a second region 36-2 of the sixth active layer may be connected with each other, and the second region 34-2 of the fourth active layer may serve as the second region 36-2 of the sixth active layer. A first region 34-1 of the fourth active layer 34 and a first region 35-1 of the fifth active layer 35 may be separately disposed. A first region 36-1 of the sixth active layer and a second region 36-2 of the sixth active layer are respectively located on two sides of the channel region of the sixth active layer along the second direction Y.

In some exemplary embodiments, the channel region 33-3 of the third active layer may have a rectangular shape, and the corners of the rectangular shape may be provided with chamfers or grooves. The channel region 33-3 of the third active layer has a first width W1 along the first direction X. The first region 33-1 of the third active layer is located on a side of the channel region 33-3 of the third active layer in the second direction Y, a first end of the first region 33-1 of the third active layer is connected to the channel region 33-3 of the third active layer, and a second end of the first region 33-1 of the third active layer extends along the second direction Y. The first region 33-1 of the third active layer has a second width W2 along the first direction X. The second width W2 is smaller than the first width W1.

In some possible exemplary embodiments, the pattern of the semiconductor layer in the display substrate may at least include a third active layer 33 of the third transistor T3, a fourth active layer 34 of the fourth transistor T4, and a fifth active layer 35 of the fifth transistor T5. The third active layer 33 and the fifth active layer 35 may be connected with each other to form an integral structure. In the first direction X, the fourth active layer 34 may be located on a side of the third active layer 33 and the fifth active layer 35 in the opposite direction of the first direction X. The fifth active layer 35 may be located on a side of the third active layer 33 in the second direction Y.

(23) Forming a pattern of a third conductive layer. This step may be described with reference to the foregoing embodiments, which will not be described in detail herein.

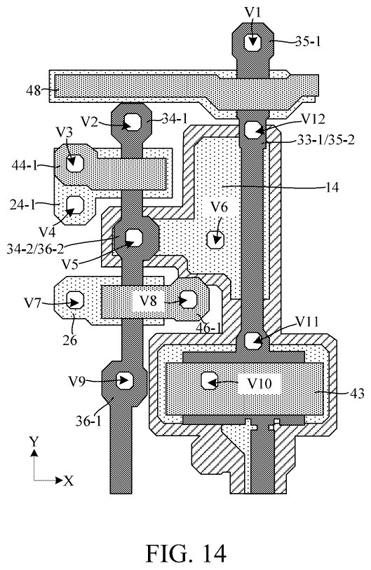

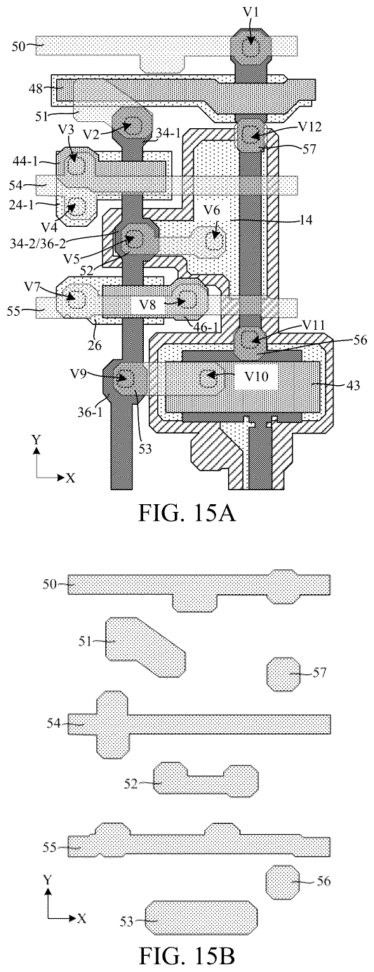

(24) Forming a pattern of a fourth insulating layer. Forming the pattern of the fourth insulating layer may include: depositing a fourth insulating thin film on the base substrate on which the above-mentioned patterns are formed, and patterning the fourth insulating thin film through a patterning process to form a fourth insulating layer covering the third conductive layer. The fourth insulating layer is provided with a plurality of vias, as shown in FIG. 14.

In some exemplary embodiments, the plurality of vias in the display substrate may at least include: a first via V1, a second via V2, a third via V3, a fourth via V4, a fifth via V5, a sixth via V6, a seventh via V7, an eighth via V8, a ninth via V9, a tenth via V10, an eleventh via V11, and a twelfth via V12. The first via V1 to the tenth via V10 may be described with reference to the foregoing embodiments, which will not be described in detail herein.

In some exemplary embodiments, an orthographic projection of the eleventh via V11 on the base substrate may be within a range of an orthographic projection of the first region 33-1 of the third active layer on the base substrate. The third insulating layer and the fourth insulating layer in the eleventh via V11 are etched away and a surface of the first region 33-1 of the third active layer is exposed. The eleventh via V11 is configured such that a first bridge electrode formed subsequently may be connected with a first end of the first region 33-1 of the third active layer through this via.

In some exemplary embodiments, an orthographic projection of the twelfth via V12 on the base substrate may be within a range of an orthographic projection of the first region 33-1 of the third active layer on the base substrate. The third insulating layer and the fourth insulating layer in the twelfth via V12 are etched away, and a surface of the first region 33-1 of the third active layer is exposed. The twelfth via V12 is configured such that a second bridge electrode formed subsequently may be connected to a second end of the first region 33-1 of the third active layer through this via.

(25) Forming a pattern of a fourth conductive layer. Forming the pattern of the fourth conductive layer may include: depositing a fourth conductive thin film on the base substrate on which the above-mentioned patterns are formed, and patterning the fourth conductive thin film through a patterning process to form the fourth conductive layer disposed on the fourth insulating layer, as shown in FIGS. 15A and 15B. FIG. 15B is a schematic plan view of the fourth conductive layer in FIG. 15A. In an exemplary embodiment, the fourth conductive layer may be referred to as a first source-drain metal (SD1) layer.

In some exemplary embodiments, the fourth conductive layer may at least include a power supply connection line 50, a first connection electrode 51, a second connection electrode 52, a third connection electrode 53, a third scan signal line 54, a fourth scan signal line 55, a first bridge electrode 56, and a second bridge electrode 57. The power supply connection line 50, the first connection electrode 51, the second connection electrode 52, the third connection electrode 53, the third scan signal line 54, and the fourth scan signal line 55 may be described with reference to the foregoing embodiments, which will not be described in detail herein.

In some exemplary embodiments, the first bridge electrode 56 may have a rectangular shape, and the first bridge electrode 56 may be located between the third connection electrode 53 and the fourth scan signal line 55. An orthographic projection of the first bridge electrode 56 on the base substrate may include an orthographic projection of the eleventh via V11 on the base substrate, and the first bridge electrode 56 may be connected to a first end of the first region of the third active layer through the eleventh via V11.

In some exemplary embodiments, the second bridge electrode 57 may have a rectangular shape, and the second bridge electrode 57 may be located between the power supply connection line 50 and the third scan signal line 54. An orthographic projection of the second bridge electrode 57 on the base substrate may include an orthographic projection of the twelfth via V12 on the base substrate, and the second bridge electrode 57 may be connected to a second end of the first region of the third active layer through the twelfth via V12.

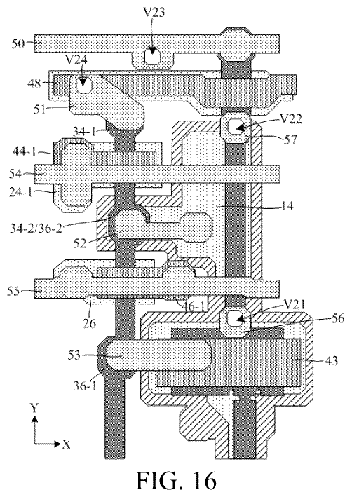

(26) Forming a pattern of a fifth insulating layer. Forming the pattern of the fifth insulating layer may include: depositing a fifth insulating thin film on the base substrate on which the above-mentioned patterns are formed, and patterning the fifth insulating thin film through a patterning process to form a fifth insulating layer covering the fourth conductive layer. The fifth insulating layer is provided with a plurality of vias, as shown in FIG. 16.

In some exemplary embodiments, the plurality of vias in the display substrate may at least include a twenty-first via V21, a twenty-second via V22, a twenty-third via V23, and a twenty-fourth via V24.

In some exemplary embodiments, an orthographic projection of the twenty-first via V21 on the base substrate may be within a range of an orthographic projection of the first bridge electrode 56 on the base substrate. The fifth insulating layer in the twenty-first via V21 is etched away, and a surface of the first bridge electrode 56 is exposed. The twenty-first via V21 is configured such that a compensation line formed subsequently may be connected to the first bridge electrode 56 through this via.

In some exemplary embodiments, an orthographic projection of the twenty-second via V22 on the base substrate may be within a range of an orthographic projection of the second bridge electrode 57 on the base substrate. The fifth insulating layer in the twenty-second via V22 is etched away, and a surface of the second bridge electrode 57 is exposed. The twenty-second via V22 is configured such that the compensation line formed subsequently may be connected with the second bridge electrode 57 through this via.

In some exemplary embodiments, an orthographic projection of the twenty-third via V23 on the base substrate may be within a range of an orthographic projection of the power supply connection line 50 on the base substrate. The fifth insulating layer in the twenty-third via V23 is etched away, and a surface of the power supply connection line 50 is exposed. The twenty-third via V23 is configured such that a first power supply line formed subsequently may be connected to the power supply connection line 50 through this via.

In some exemplary embodiments, an orthographic projection of the twenty-fourth via V24 on the base substrate may be within a range of an orthographic projection of the first connection electrode 51 on the base substrate. The fifth insulating layer in the twenty-fourth via V24 is etched away, and a surface of the first connection electrode 51 is exposed. The twenty-fourth via V24 is configured such that a data signal line formed subsequently may be connected with the first connection electrode 51 through this via.

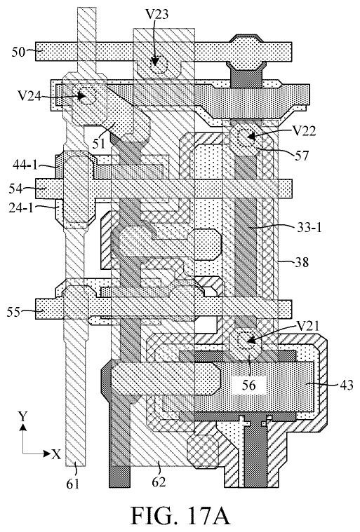

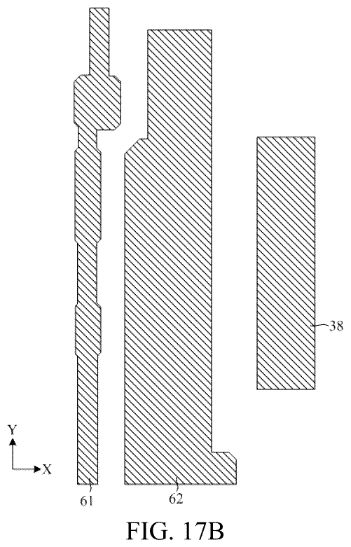

(27) Forming a pattern of a fifth conductive layer. Forming the pattern of the fifth conductive layer may include: depositing a fifth conductive thin film on the base substrate on which the above-mentioned patterns are formed, and patterning the fifth conductive thin film through a patterning process to form the fifth conductive layer disposed on the fifth insulating layer, as shown in FIGS. 17A and 17B. FIG. 17B is a schematic plan view of the fifth conductive layer in FIG. 17A. In an exemplary implementation, the fifth conductive layer may be referred to as a second source-drain metal (SD2) layer.

In some exemplary embodiments, the fourth conductive layer may at least include a data signal line 61, a first power supply line 62, and a compensation line 38. The first power supply line 62 may be located between the data signal line 61 and the compensation line 38. The data signal line 61, the first power supply line 62, and the compensation line 38 may have a straight line shape extending along the second direction Y.

In some exemplary embodiments, an orthographic projection of the data signal line 61 on the base substrate partially overlaps with an orthographic projection of the first connection electrode 51 on the base substrate, and the orthographic projection of the data signal line 61 on the base substrate may include an orthographic projection of the twenty-fourth via V24 on the base substrate. The data signal line 61 may be connected to the first connection electrode 51 through the twenty-fourth via V24, and the first connection electrode 51 is connected to the first region of the fourth active layer, thus realizing the connection of the data signal line 61 to the first region of the fourth active layer.

In some exemplary embodiments, an orthographic projection of the first power supply line 62 on the base substrate partially overlaps with an orthographic projection of the power supply connection line 50 on the base substrate, and the orthographic projection of the first power supply line 62 on the base substrate may include an orthographic projection of the twenty-third via V23 on the base substrate. The first power supply line 62 may be connected to the power supply connection line 50 through the twenty-third via V23 to form a grid structure for transmitting the first power supply signal. This design may not only effectively reduce a resistance of the first power supply line, and reduce a voltage drop of the first power supply signal, but also may effectively improve uniformity of the first power supply signal in the display substrate, effectively improve uniformity of display, and improve display attribute and display quality.

In some exemplary embodiments, an orthographic projection of the compensation line 38 on the base substrate may include orthographic projections of the twenty-first via V21 and the twenty-second via V22 on the base substrate, the compensation line 38 may be connected to the first bridge electrode 56 through the twenty-first via V21, and the compensation line 38 may be connected to the second bridge electrode 57 through the twenty-second via V22. The orthographic projection of the compensation line 38 on the base substrate partially overlaps with an orthographic projection of the first region 33-1 of the third active layer on the base substrate. For example, the orthographic projection of the compensation line 38 on the base substrate includes the orthographic projection of the first region 33-1 of the third active layer on the base substrate. The compensation line 38 and the first region 33-1 of the third active layer may form a parallel connection path, thereby reducing the on-resistance of the third transistor, and improving the problem of the threshold voltage divergence of the third transistor.

The manufacturing process in the embodiment of the present disclosure may be compatible well with an existing manufacturing process, is simple in process implementation, is easy to implement, and has a high production efficiency, a low production cost, and a high yield.

In some exemplary embodiments, the first conductive layer, the second conductive layer, the third conductive layer, the fourth conductive layer and the fifth conductive layer may be made of metal materials, such as any one or more of silver (Ag), copper (Cu), aluminum (Al) and molybdenum (Mo), or alloy materials of the above metals, such as an aluminum neodymium alloy (AlNd) or a molybdenum niobium alloy (MoNb), and may be a single-layer structure or a multi-layer composite structure, such as Mo/Cu/Mo, etc. The first insulating layer, the second insulating layer, the third insulating layer, and the fourth insulating layer may be made of any one or more of Silicon Oxide (SiOx), Silicon Nitride (SiNx), and Silicon Oxynitride (SiON), and may be a single layer, a multi-layer, or a composite layer. The material of the fifth insulating layer may be one or more of an epoxy resin, or a phenolic resin, or a urea-formaldehyde resin, or a melamine-formaldehyde resin, or a furan resin, or a silicone resin, or a polyester resin, or a polyamide resin, or an acrylic resin, or a polyurethane, or a vinyl resin, or a hydrocarbon resin, or a polyether resin. The active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene. That is, the present disclosure is applicable to a transistor that is manufactured based on an oxide technology, a silicon technology, or an organic matter technology. The structures and the manufacturing process thereof shown in the embodiments of the present disclosure are merely exemplary description. In an exemplary implementation, a corresponding structure may be changed and patterning processes may be added or reduced according to actual needs, which is not limited here in the present disclosure.

An embodiment of the present disclosure further provides a display apparatus which includes the display substrate described in any of the aforementioned embodiments. The display apparatus may be any product or component with a display function, such as a mobile phone, a tablet computer, a television, a display, a laptop computer, a digital photo frame, and a navigator, and an embodiment of the present disclosure is not limited thereto.

Although the embodiments disclosed in the present disclosure are described as above, the described contents are only embodiments which are adopted in order to facilitate understanding of the present disclosure, and are not intended to limit the present disclosure. It should be noted that the above examples or embodiments are exemplary only but not restrictive. Therefore, the present disclosure is not limited to what is specifically shown and described here. Various modifications, substitutions, or omissions may be made in forms and details of implementations without departing from the scope of the present disclosure.

1. A display substrate, comprising a base substrate and at least one pixel driving circuit located on a side of the base substrate; wherein the at least one pixel driving circuit comprises at least one transistor, the at least one transistor comprises an active layer, and the active layer comprises a channel region, and a first region and a second region located on opposite sides of the channel region; the first region has a first end and a second end oppositely disposed, the first end of the first region is connected to the channel region, and the second end extends along a second direction; and
the channel region has a first width along a first direction, the first region has a second width along the first direction, the first width is greater than the second width; and the display substrate further comprises a compensation line, a first end of the compensation line is connected to the channel region, and a second end of the compensation line is connected to the second end of the first region; wherein the first direction intersects with the second direction.

2. The display substrate according to claim 1, wherein an absolute value of a difference between the first width and the second width is greater than 10% of the first width.

3. The display substrate according to claim 1, wherein the display substrate further comprises at least one capacitor, and the at least one capacitor is closer to the base substrate than the compensation line, and the at least one capacitor is located on a side of an extension direction of the compensation line; a capacitor of the at least one capacitor comprises two plates disposed oppositely, and an orthographic projection of the compensation line on the base substrate does not overlap with either of orthographic projections of the two plates on the base substrate.

4. The display substrate according to claim 3, wherein the compensation line and the active layer are disposed in a same layer.

5. The display substrate according to claim 4, further comprising a first connection bridge, wherein the first connection bridge has a first end and a second end disposed oppositely along the first direction; the first end of the first connection bridge is connected to the second end of the compensation line, and the second end of the first connection bridge is connected to the second end of the first region of the active layer.

6. The display substrate according to claim 5, further comprising at least one second connection bridge; wherein the at least one second connection bridge is located between the first connection bridge and the channel region, and located between the first region and the compensation line; a second connection bridge of the at least one second connection bridge extends along the first direction and comprises a first end and a second end disposed oppositely; the first end of the second connection bridge is connected to the compensation line, and the second end of the second connection bridge is connected to the first region.

7. The display substrate according to claim 6, wherein the first connection bridge, the at least one second connection bridge, and the compensation line are connected to each other to form an integral structure.

8. The display substrate according to claim 1, wherein the compensation line is located on a side of the active layer away from the base substrate.

9. The display substrate according to claim 8, wherein in a plane perpendicular to the display substrate, the display substrate further comprises a semiconductor layer, a first source-drain metal layer, and a second source-drain metal layer located sequentially on a side of the base substrate; and
the active layer is located in the semiconductor layer, and the compensation line is located in the first source-drain metal layer or the second source-drain metal layer.

10. The display substrate according to claim 9, further comprising a first bridge electrode and a second bridge electrode; wherein an orthographic projection of the first bridge electrode on the base substrate at least partially overlaps with an orthographic projection of the first end of the first region on the base substrate, and an orthographic projection of the second bridge electrode on the base substrate at least partially overlaps with an orthographic projection of the second end of the first region on the base substrate; an orthographic projection of the compensation line on the base substrate partially overlaps with both the orthographic projection of the first bridge electrode on the base substrate and the orthographic projection of the second bridge electrode on the base substrate; and
wherein the compensation line is connected to the first end of the first region through the first bridge electrode, and the compensation line is connected to the second end of the first region through the second bridge electrode.

11. The display substrate according to claim 10, wherein the first bridge electrode and the second bridge electrode are both located in the first source-drain metal layer, and the compensation line is located in the second source-drain metal layer.

12. The display substrate according to claim 9, wherein an orthographic projection of the compensation line on the base substrate at least partially overlaps with an orthographic projection of the first region on the base substrate.

13. The display substrate according to claim 10, wherein the orthographic projection of the compensation line on the base substrate is within an orthographic projection of the first region on the base substrate.

14. The display substrate according to claim 1, wherein the at least one transistor is a drive transistor; the at least one pixel driving circuit further comprises a light emitting control transistor connected to the second end of the first region.

15. A display apparatus, comprising the display substrate according to claim 1.

16. The display substrate according to claim 2, wherein the at least one transistor is a drive transistor; the at least one pixel driving circuit further comprises a light emitting control transistor connected to the second end of the first region.

17. The display substrate according to claim 3, wherein the at least one transistor is a drive transistor; the at least one pixel driving circuit further comprises a light emitting control transistor connected to the second end of the first region.

18. The display substrate according to claim 4, wherein the at least one transistor is a drive transistor; the at least one pixel driving circuit further comprises a light emitting control transistor connected to the second end of the first region.

19. The display substrate according to claim 5, wherein the at least one transistor is a drive transistor; the at least one pixel driving circuit further comprises a light emitting control transistor connected to the second end of the first region.

20. The display substrate according to claim 6, wherein the at least one transistor is a drive transistor; the at least one pixel driving circuit further comprises a light emitting control transistor connected to the second end of the first region.
